(19) United States
(12) Patent Application Publication
(10) Pub. No.: US 2010/0213458 A1
(43) Pub. Date: Aug. 26, 2010

(54) RIGID SEMICONDUCTOR MEMORY HAVING AMORPHOUS METAL OXIDE SEMICONDUCTOR CHANNELS

(75) Inventor: Kirk D. Prall, Boise, ID (US)

Correspondence Address: LEFFERT JAY & POLGLAZE, P.A., P.O. BOX 581009, MINNEAPOLIS, MN, 55458-1009, US

(73) Assignee: Micron Technology, Inc.

(21) Appl. No.: 12/390,703

(22) Filed: Feb. 23, 2009

(51) Int. Cl. H01L 29/12; H01L 21/34

(52) U.S. Cl. 257/43; 438/104; 257/E29.068; 257/E21.459

(57) ABSTRACT

Rigid semiconductor memory using amorphous metal oxide semiconductor channels are useful in the production of thin-film transistor memory devices. Such devices include single-layer and multi-layer memory arrays of volatile or non-volatile memory cells. The memory cells can be formed to have a gate stack overlying an amorphous metal oxide semiconductor, with amorphous metal oxide semiconductor channels.

### TECHNICAL FIELD

The present invention relates generally to semiconductor memory, and in particular, in one or more embodiments, the present disclosure relates to rigid thin-film transistor (TFT) memory arrays using amorphous metal oxide semiconductor channels.

### BACKGROUND

Memory devices are typically provided as internal, semiconductor, integrated circuits in computers or other electronic devices. There are many different types of memory including random-access memory (RAM), read only memory (ROM), dynamic random access memory (DRAM), synchronous dynamic random access memory (SDRAM), and flash memory.

Flash memory devices have developed into a popular source of non-volatile memory for a wide range of electronic applications. Flash memory devices typically use a one-transistor memory cell that allows for high memory densities, high reliability, and low power consumption. Changes in threshold voltage of the cells, through programming of charge storage nodes (e.g., floating gates or trapping layers) or other physical phenomena (e.g., phase change or polarization), determine the data value of each cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

Flash memory typically utilizes one of two basic architectures known as NOR flash and NAND flash. The designation is derived from the logic used to read the devices. In NOR flash architecture, a column of memory cells are coupled in parallel with each memory cell coupled to a data line, commonly referred to as a bit line. In NAND flash architecture, a column of memory cells are coupled in series with only the first memory cell of the column coupled to a bit line.

As memory device scaling advances, the technology challenges generally increase. One approach to increase memory density without reducing sizing of individual memory cells has been to explore multi-layer memory. In multi-layer memory, multiple layers of memory devices are stacked to increase the memory density and reduce cost. Although this approach mitigates problems of reducing feature sizing, other problems are introduced. For example, a semiconductor substrate of polycrystalline silicon, generally referred to a polysilicon, can be used to form multi-layer memory. However, disadvantages of such resulting memory cells include high off-state leakage, poor Iₒₙ/I_{off} ratio, and poor carrier mobility. Alternatively, a semiconductor substrate of single-crystal silicon can be used. However, this approach involves the formation of high-quality epitaxial silicon, which is costly compared to forming a single layer of memory cells on a silicon wafer. As a result, such constructions have not become commercially practicable.

For the reasons stated above, and for other reasons which will become apparent to those skilled in the art upon reading and understanding the present specification, there is a need in the art for alternative constructions for multi-layer memory devices.

### BRIEF DESCRIPTION OF THE DRAWINGS

FIG. 1 is a simplified block diagram of a memory device coupled to a processor as part of an electronic system, according to an embodiment of the disclosure.

FIGS. 2A-2D are cross-sectional views of a portion of a memory array during various stages of fabrication in accordance with embodiments of the disclosure.

FIG. 3 is a cross-sectional view of a multi-layer memory array in accordance with another embodiment of the disclosure.

### DETAILED DESCRIPTION

In the following detailed description of the present embodiments, reference is made to the accompanying drawings that form a part hereof, and in which is shown by way of illustration specific embodiments in which the disclosure may be practiced. These embodiments are described in sufficient detail to enable those skilled in the art to practice the invention, and it is to be understood that other embodiments may be utilized and that process, chemical, electrical or mechanical changes may be made without departing from the scope of the present disclosure. When reference is made to a wafer or substrate in the following description, previous process steps may have been utilized to form regions/junctions in the base semiconductor structure, and terms wafer or substrate include the underlying layers containing such regions/junctions. In addition, directional references, e.g., upper, lower, top, bottom and sides, are relative to one another and need not refer to an absolute direction. The following detailed description is, therefore, not to be taken in a limiting sense.

Multi-layer memory arrays of the prior art have been formed on crystalline substrates, such as polysilicon. However, such memory cells have disadvantages including high off-state leakage, poor Iₒₙ/I_{off} ratio, and poor carrier mobility, as noted above. In addition, as device dimensions decrease, variations due to polysilicon grain boundaries become more pronounced. Such variations include charge leakage along the boundaries, recombination and generation along the boundaries, and variation in conductance along the boundaries. These variations can cause severe problems in memory arrays because differing characteristics among the transistors can lead to sensing, programming and erasing uniformity problems. The problems of polysilicon can be avoided through the use of single-crystal epitaxial silicon. However, epitaxial silicon is difficult and costly to produce for such applications, typically requiring thick high-quality epitaxial silicon growth. As a result, such constructions have not become commercially practicable.

Various embodiments include memory arrays formed on amorphous metal oxide semiconductors. Amorphous oxide semiconductors have long been recognized for their use in transparent and flexible thin-film transistor (TFT) devices, where crystalline semiconductor materials are disfavored. In contrast, crystalline semiconductor materials are the norm in rigid TFT devices.

Flexible TFT devices are relatively large compared to typical rigid TFT devices formed on crystalline substrates. For example, transistors in flexible TFT devices may be three or more orders of magnitude larger than transistors in rigid TFT devices. For this reason, applicability in flexible TFT devices has not been thought to extrapolate to use in rigid TFT memory devices.

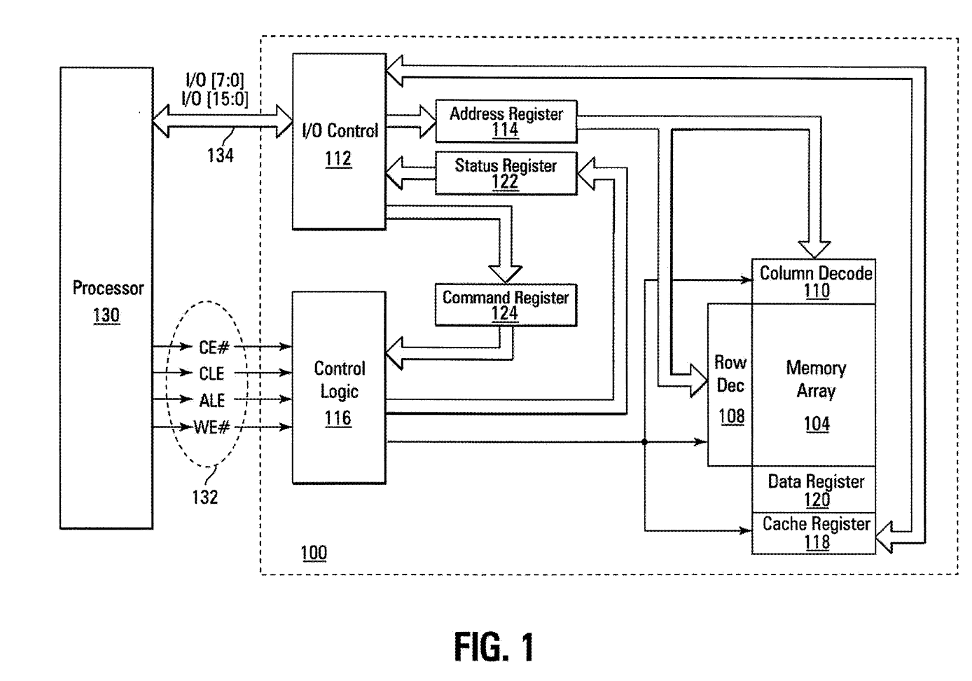

FIG. 1 is a simplified block diagram of a memory device 100, as one example of an integrated circuit device, in communication with (e.g., coupled to) a processor 130 as part of an electronic system, according to an embodiment of the disclosure. Some examples of electronic systems include personal computers, personal digital assistants (PDAs), digital cameras, digital media players, digital recorders, games, appliances, vehicles, wireless devices, cellular telephones and the like. The processor 130 may be a memory controller or other external processor.

Memory device 100 includes an array of memory cells 104 logically arranged in rows and columns. The array of memory cells 104 includes memory cells having amorphous metal oxide semiconductor channels. The array of memory cells 104 may be a single-layer memory array or a multi-layer memory array. Although various embodiments will be described primarily with reference to NAND memory arrays, the various embodiments are not limited to a specific architecture of the memory array 104. Some examples of other array architectures suitable for the present embodiments include NOR arrays, AND arrays or other arrays.

A row decode circuitry 108 and a column decode circuitry 110 are provided to decode address signals. Address signals are received and decoded to access memory array 104. Memory device 100 also includes input/output (I/O) control circuitry 112 to manage input of commands, addresses and data to the memory device 100 as well as output of data and status information from the memory device 100. An address register 114 is coupled between I/O control circuitry 112 and row decode circuitry 108 and column decode circuitry 110 to latch the address signals prior to decoding. A command register 124 is coupled between I/O control circuitry 112 and control logic 116 to latch incoming commands. Control logic 116 controls access to the memory array 104 in response to the commands and generates status information for the external processor 130. The control logic 116 is coupled to row decode circuitry 108 and column decode circuitry 110 to control the row decode circuitry 108 and column decode circuitry 110 in response to the addresses.

Control logic 116 is also coupled to a cache register 118. Cache register 118 latches data, either incoming or outgoing, as directed by control logic 116 to temporarily store data while the memory array 104 is busy writing or reading, respectively, other data. During a write operation, data is passed from the cache register 118 to data register 120 for transfer to the memory array 104; then new data is latched in the cache register 118 from the I/O control circuitry 112. During a read operation, data is passed from the cache register 118 to the I/O control circuitry 112 for output to the external processor 130; then new data is passed from the data register 120 to the cache register 118. A status register 122 is coupled between I/O control circuitry 112 and control logic 116 to latch the status information for output to the processor 130.

Memory device 100 receives control signals at control logic 116 from processor 130 over a control link 132. The control signals may include a chip enable CE#, a command latch enable CLE, an address latch enable ALE, and a write enable WE#. Memory device 100 receives commands (in the form of command signals), addresses (in the form of address signals), and data (in the form of data signals) from processor 130 over a multiplexed input/output (I/O) bus 134 and outputs data to processor 130 over I/O bus 134.

Specifically, the commands are received over input/output (I/O) pins [7:0] of I/O bus 134 at I/O control circuitry 112 and are written into command register 124. The addresses are received over input/output (I/O) pins [7:0] of bus 134 at I/O control circuitry 112 and are written into address register 114. The data are received over input/output (I/O) pins [7:0] for an 8-bit device or input/output (I/O) pins [15:0] for a 16-bit device at I/O control circuitry 112 and are written into cache register 118. The data are subsequently written into data register 120 for programming memory array 104. For another embodiment, cache register 118 may be omitted, and the data are written directly into data register 120. Data are also output over input/output (I/O) pins [7:0] for an 8-bit device or input/output (I/O) pins [15:0] for a 16-bit device. It will be appreciated by those skilled in the art that additional circuitry and signals can be provided, and that the memory device of FIG. 1 has been simplified to help focus on the present disclosure. Additionally, while the memory device of FIG. 1 has been described in accordance with popular conventions for receipt and output of the various signals, it is noted that the various embodiments are not limited by the specific signals and I/O configurations described unless expressly noted herein.

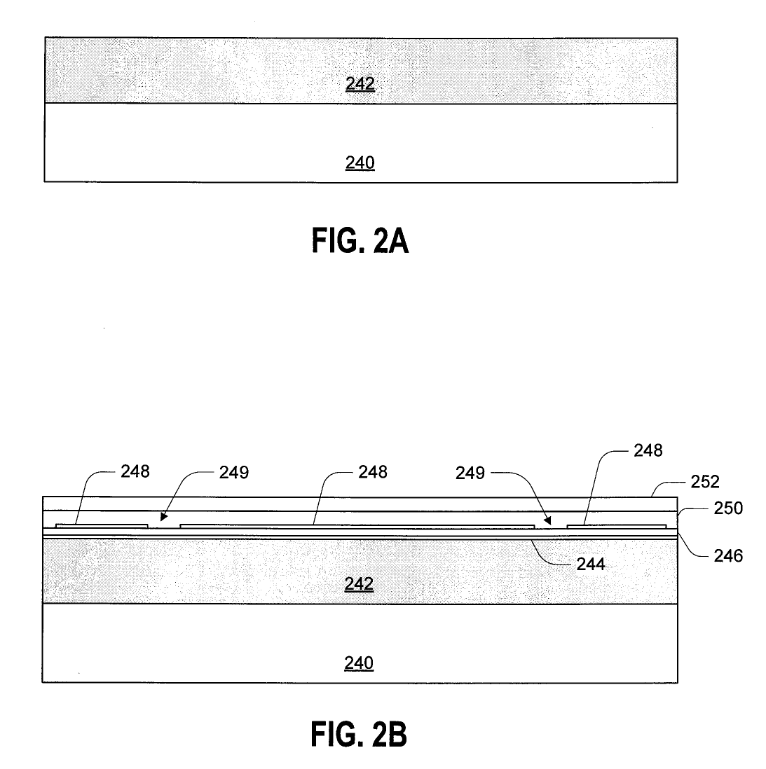

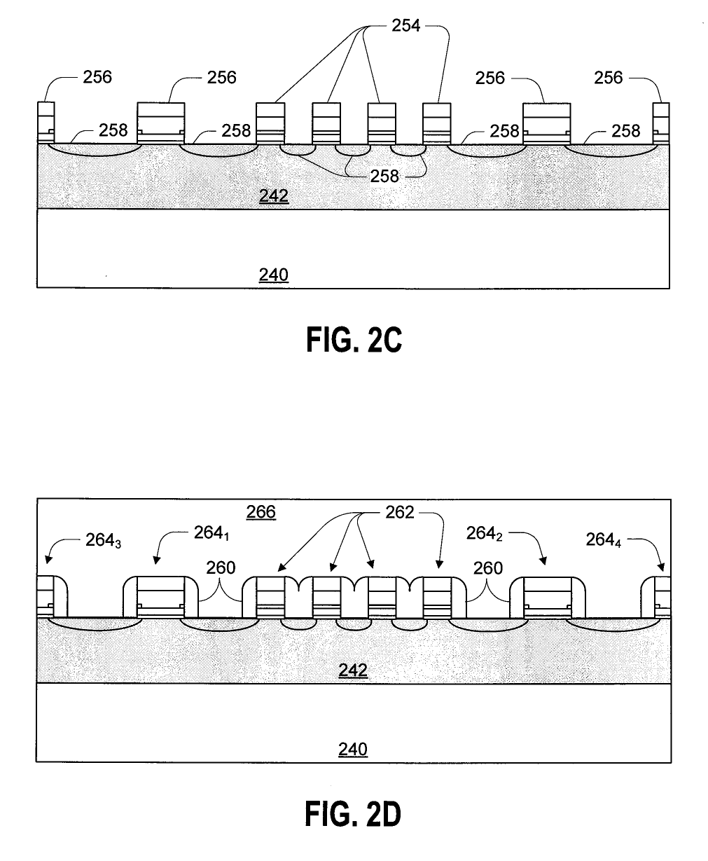

FIGS. 2A-2D are cross-sectional views of a portion of a memory array during various stages of fabrication in accordance with embodiments of the disclosure. Some reference numerals, following their introduction, are not shown in remaining figures for clarity. While the figures depict the fabrication of floating-gate memory cells in a NAND array architecture, other memory cell structures and array architectures may be used. For example, the memory array could include other non-volatile memory cells, such as nitride read-only memory (NROM) cells, ferroelectric field-effect transistor memory cells, phase-change memory cells and other memory cells capable of using changes in threshold voltage, resistance or other characteristics to store a data value, or volatile memory cells, such as DRAM cells using a separate charge node, e.g., a capacitor, to store charge indicative of a data value. Example alternative array architectures include NOR arrays, AND arrays, or other arrays.

FIG. 2A depicts a portion of the memory array after one or more processing steps have occurred. FIG. 2A depicts an amorphous metal oxide semiconductor (AMOS) 242 formed overlying a support material 240. Although the AMOS 242 may be formed on the support material 240, as depicted in FIG. 2A, alternate structures could include one or more intervening materials (not shown in FIG. 2A), such as adhesion layers, dielectric materials, isolated active areas, etc.

The support material 240 may be a semiconductor material, such as a monocrystalline silicon substrate. For example, if the desire is to form a first layer of a multi-layer memory array, there is no need to isolate the future memory cells from an underlying layer, such that a semiconductor material would not interfere with operation of the memory device. Alternatively, the support material 240 may be a dielectric material. As one example, the support material 240 could be a doped silicate material, such as borophosphosilicate glass (BPSG). Using a dielectric support material 240 would provide isolation of the future memory cells from underlying memory cells or other active areas. For a single-layer memory array, the support material 240 is rigid. As used herein, rigid means that although the structure may flex when stress is applied, it will tend to return to its original position and orientation when that stress is removed, provided that the stress is not excessive to the point of causing structural failure. For example, the rigid support material 240 might be a monocrystalline silicon substrate.

The AMOS 242 represents the conducting channel of future IC devices, such a memory cells, select gates, peripheral devices, etc. AMOS 242 is an amorphous material, thus not suffering from the grain boundary problems of polycrystalline silicon. Furthermore, amorphous metal oxides for use with various embodiments include ionic amorphous metal oxide semiconductors whose primary or sole bonding mechanism is ionic rather than covalent. Examples include indium-doped tin oxide (ITO or InₓSnO₂), zinc tin oxide (ZTO or ZnₓOₓSnO₂), indium gallium zinc oxide (InGaZnO₄ or InGa₃(ZnO)₅), zinc oxide (ZnO), tin oxide (SnO₂), indium gallium oxide (In₂O₃Ga₂O₃), indium oxide (In₂O₃) and cadmium oxide (CdO).

Amorphous metal oxides may be formed by a variety of methods. For example, a physical vapor deposition (PVD) process may be used. Examples of PVD include evaporative deposition, where a target material is heated to vaporization; electron beam evaporation, where an electron beam is used to vaporize a target anode; pulsed-laser deposition, where a laser is used to ablate a target material; and sputtering, where a target material is subjected to a plasma to release its component materials. In flexible TFT uses of amorphous metal oxides, a compromise is made between electrical conductivity and optical transmittance, i.e., a driving goal is to maintain transparency of the oxide materials at a cost of conductivity. As the level of charge carriers increases in such materials, they become more opaque. However, in various embodiments described herein, optical transmittance is not a concern. Thus, amorphous metal oxides as used in embodiments of this disclosure can be formed with a high level of charge carriers without concern for their optical properties. Increasing levels of charge carriers can be obtained by decreasing partial pressures of oxygen (O₂), or increasing availability of an impurity, such as hydrogen (H₂), during formation of the amorphous metal oxide materials. For one embodiment, the amorphous metal oxide semiconductors are formed to have sufficient charge carriers such that the material is opaque. For another embodiment, the amorphous metal oxide semiconductors are formed to have a sufficient charge carrier density such that the material has a transmittance of less than 70%. In addition, the temperature of the surface upon which the desired material is being deposited should be maintained below a crystallization temperature of that material in order to maintain the amorphous character of the deposited material. For example, many such materials should be formed at temperatures below about 200° C. to maintain an amorphous morphology.

The AMOS 242 may be formed to have a first conductivity type, such as a p-type conductivity or an n-type conductivity. The AMOS 242 may be inherently of a specific conductivity type. For example, indium-doped tin oxide is inherently an n-type material. A conductivity type may be enhanced or altered through chemical doping of the AMOS material. For example, the charge valence of cations and anions can be altered by altering the partial pressure of oxygen (O₂) during formation of the AMOS material or through implantation of cations of low electron affinity after formation.

FIG. 2B depicts a portion of the memory array after several processing steps have occurred. Formation of the type of structure depicted in FIG. 2B is well known and will not be detailed herein. In general, FIG. 2B may depict a stack of materials from which future memory cell gate stacks are to be formed. For one embodiment, these materials include a tunnel dielectric material 244, a floating gate material 246, an intergate dielectric material 248, a control gate material 250 and cap material 252 formed on the AMOS 242. Note that portions of the intergate dielectric material 248 are removed to form slots 249 where future select gates will be formed. Removing intergate dielectric material 248 in these areas permits the floating gate material 246 and the control gate material 250 to act as a single conductor in the future select gates for improved conduction and faster operation. The memory array of FIGS. 2B-2D will be discussed with reference to floating-gate non-volatile memory cells, although the concepts apply to other types of memory cells. For example, the materials 244, 246 and 248 could represent a charge-trapping floating node arrangement, such as an ONO (oxide-nitride-oxide) structure of an NROM memory cell. Because the chosen materials for the gate stacks are not a feature or limitation of the invention, other structures may be chosen for formation using the AMOS 242.

In FIG. 2C, access line gate stacks 254 have been defined for future memory cells of a NAND string and select line gate stacks 256 have been defined for future select line gates for the NAND string. Such patterning is common in the art of semiconductor fabrication. As one example, a photolithographic resist (photoresist) material could be deposited overlying the cap material 252, exposed to a radiation source, such as UV light, and developed to define areas overlying the cap material 252 for removal. Following this patterning of the photoresist material, exposed portions of the cap material 252 and underlying materials are removed, such as by etching or other removal process, to expose the AMOS 242. More than one removal process may be used where the chosen removal process is ineffective at removing an underlying material. Note that the portion of the memory array depicted in FIG. 2C includes select line gate stacks of two adjacent NAND strings. Source/drain regions 258 are formed, such as by chemical doping of exposed portions of the AMOS 242.

In FIG. 2D, dielectric spacers 260 may also be formed. As one example, a blanket deposit of some dielectric material, e.g., silicon nitride, is formed overlying the gate stacks 254/256 followed by an anisotropic removal of the blanket deposit to form spacers and expose portions of the AMOS 242. A bulk dielectric material 266 is then formed to insulate memory cells 262 and select line gates 264. The bulk dielectric material 266 may be any dielectric material. As one example, the bulk dielectric material 266 is a doped silicate material, such as borophosphosilicate glass (BPSG). The bulk dielectric material 266 may also form the support 240 for a subsequent array of memory cells to be formed over the structure depicted in FIG. 2D. The select line gate 264₁ may selectively connect the NAND string of memory cells 262 to a data line of the memory array while the select line gate 264₂ may selectively connect the NAND string of memory cells 262 to a source line of the memory array. The select line gate 264₃ may selectively connect another NAND string of memory cells (not shown) to the data line while the select line gate 264₄ may selectively connect yet another NAND string of memory cells (not shown) to the source line. Although FIG. 2D depicts a NAND string of memory cells 262 to contain four memory cells coupled in series source-to-drain, the NAND strings can include any number of memory cells 262 and it is common for NAND strings to contain more than four memory cells in series. For example, many typical NAND flash memory devices have 32 memory cells in each NAND string. Furthermore, although FIG. 2D depicts formation of memory cells on a flat surface having horizontal channels, memory devices are known that form pillars of semiconductor material in which memory cells are formed on the opposing sidewalls of the pillars having vertical channels. While not necessary for an understanding of the present disclosure, U.S. Pat. No. 5,936,274, issued Aug. 10, 1999 to Forbes et al. shows such a structure. Thus, the amorphous metal oxide semiconductor may be used for memory structures having vertical channels as well.

The memory array, of which a portion is depicted in FIG. 2D, is a rigid structure. Channels of the memory cells 262 are defined by portions of the AMOS 242 interposed between their source/drain regions 258. Where a data value of a memory cell is defined by a threshold voltage of a transistor, such as in many non-volatile memory devices, these one or more of these transistors are formed to have amorphous metal oxide semiconductor channels. Where a data value of a memory cell is defined by a charge stored in a separate charge-storage node that is accessed by a transistor, such as in many volatile memory devices, one or more of these transistors are formed to have amorphous metal oxide semiconductor channels. In either such situation, they are generically deemed to have memory cells having amorphous metal oxide semiconductor channels.

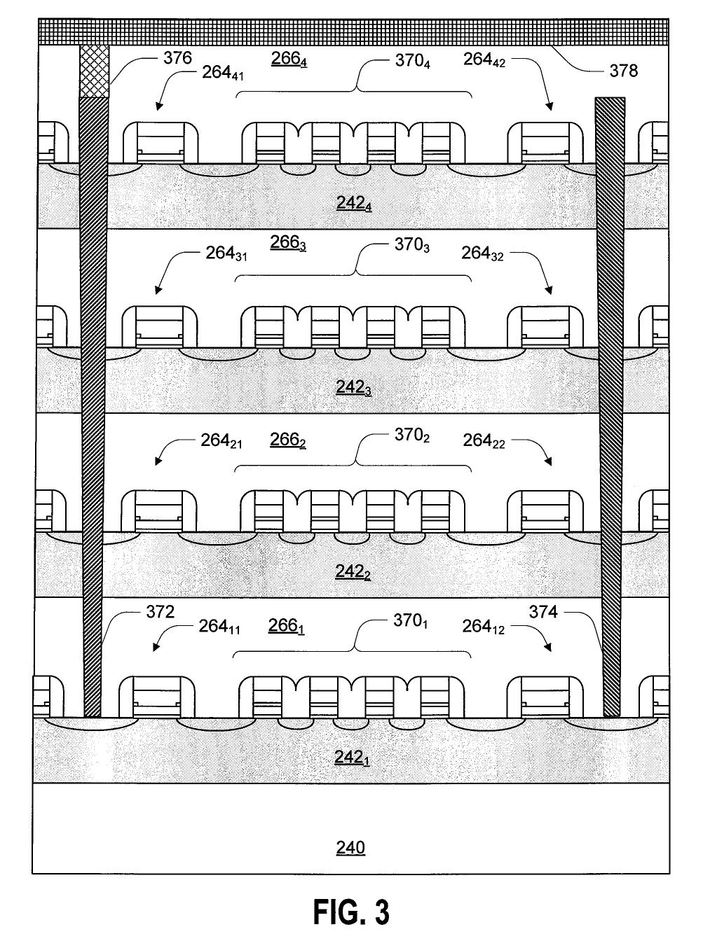

FIG. 3 is a cross-sectional view of a multi-layer memory array in accordance with another embodiment of the disclosure. The multi-layer memory array of FIG. 3 is depicted to contain four layers. However, fewer or more layers may also be used.

A first layer of the multi-layer memory array contains a first NAND string 370₁ of memory cells formed on a first amorphous metal oxide semiconductor 242₁. The first amorphous metal oxide semiconductor 242₁ is formed overlying a support material 240. Support material 240 is a rigid support material. Although the first amorphous metal oxide semiconductor 242₁ may be formed on the support material 240, as depicted in FIG. 3, alternate structures could include one or more intervening materials (not shown in FIG. 3).

The first NAND string 370₁ has a first end selectively connected to a data line contact 372 through a first select line gate 264₁₁ and a second end selectively connected to a source line contact 374 though a second select line gate 264₁₂. Although depicted as single gates in the figures, select line gates 264 may alternatively represent two or more gates in series. A first dielectric 266₁ is formed overlying the first layer to isolate first NAND string 370₁ and other active structures from overlying active areas, e.g., additional layers of the multi-layer memory array.

A second layer of the multi-layer memory array contains a second NAND string 370₂ of memory cells formed on a second amorphous metal oxide semiconductor 242₂. The second NAND string 370₂ has a first end selectively connected to a data line contact 372 through a first select line gate 264₂₁ and a second end selectively connected to a source line contact 374 though a second select line gate 264₂₂. A second dielectric 266₂ is formed overlying the second layer to isolate second NAND string 370₂ and other active structures from overlying active areas, e.g., additional layers of the multi-layer memory array.

A third layer of the multi-layer memory array contains a third NAND string 370₃ of memory cells formed on a third amorphous metal oxide semiconductor 242₃. The third NAND string 370₃ has a first end selectively connected to a data line contact 372 through a first select line gate 264₃, and a second end selectively connected to a source line contact 374 though a second select line gate 264₃₂. A third dielectric 266₃ is formed overlying the third layer to isolate third NAND string 370₃ and other active structures from overlying active areas, e.g., additional layers of the multi-layer memory array.

A fourth layer of the multi-layer memory array contains a fourth NAND string 370₄ of memory cells formed on a fourth amorphous metal oxide semiconductor 242₄. The fourth NAND string 370₄ has a first end selectively connected to a data line contact 372 through a first select line gate 264₄₁ and a second end selectively connected to a source line contact 374 though a second select line gate 264₄₂. A fourth dielectric 266₄ is formed overlying the fourth layer to isolate fourth NAND string 370₄ and other active structures from overlying active areas, e.g., data line 378.

The layers of the multi-layer memory array can be formed as described with reference to FIGS. 2A-2D. The amorphous metal oxide semiconductors 242₁, 242₂, 242₃ and 242₄ may be of the same type, e.g., all an indium-doped tin oxide. While there is perceived benefit in forming the memory cells of each layer of the array on the same semiconductor, there is no prohibition in forming the memory cells of one layer on a different semiconductor than one or more other layers of the memory device.

Data line contact 372 and source line contact 374 may be formed after all of the layers of the multi-layer memory array are complete. For example, after completing formation of the fourth NAND string 370₄, at least a portion of the fourth dielectric 266₄ is formed, e.g., to a desired level of the top of the source line 374. Contact holes are then formed down through the layers to at least a surface of the first amorphous metal oxide semiconductor 242₁ and are filled with a conductive material. In this manner, source/drain regions of the first select line gates 264₁₁, 264₂₁, 264₃₁ and 264₄₁ are commonly connected to the data line contact 372 and source/drain regions of the second select line gates 264₁₂, 264₂₂, 264₃₂ and 264₄₂ are commonly connected to the source line contact 374. Alternatively, the source line contact 374 can also form the source line for the memory array. For example, instead of forming a contact hole for source line contact 374, a trench could be formed through source/drain regions for additional NAND strings (not shown) formed behind or in front of the face plane of FIG. 3.

After forming the data line contact 372 and the source line contact 374 (or source line), a remaining portion of the fourth dielectric 266₄ may be formed, a conductive plug 376 may be formed to be in contact with the data line contact 372, and a data line 378 may be formed overlying the fourth dielectric 266₄ in contact with the conductive plug 376. Remaining connections to peripheral devices, such as address decoders, sensing devices and I/O control, are well within the abilities of those skilled in the art of semiconductor fabrication. Similarly, formation of other memory array types, containing different memory cells or architectures, are also well within the abilities of those skilled in the art of semiconductor fabrication in view of the foregoing disclosure.

Although specific embodiments have been illustrated and described herein, it will be appreciated by those of ordinary skill in the art that any arrangement that is calculated to achieve the same purpose may be substituted for the specific embodiments shown. Many adaptations of the disclosure will be apparent to those of ordinary skill in the art. Accordingly, this application is intended to cover any adaptations or variations of the disclosure.

What is claimed is:

1. A memory device, comprising:
a plurality of memory cells having channels of amorphous metal oxide semiconductor; and
a rigid support material underlying the amorphous metal oxide semiconductor.

2. The memory device of claim 1, wherein the rigid support material is a monocrystalline silicon.

3. The memory device of claim 1, wherein the amorphous metal oxide semiconductor is formed on the rigid support material.

4. The memory device of claim 1, wherein the plurality of memory cells comprises memory cells selected from the group consisting of floating-gate memory cells, nitride read-only memory cells, ferroelectric field-effect transistor memory cells, phase-change memory cells and dynamic random access memory cells.

5. The memory device of claim 1, wherein the amorphous metal oxide semiconductor is an ionic amorphous metal oxide semiconductor.

6. The memory device of claim 5, wherein the ionic amorphous metal oxide semiconductor is selected from the group consisting of indium-doped tin oxide, zinc tin oxide, indium gallium zinc oxide, zinc oxide, tin oxide, indium gallium oxide, indium oxide and cadmium oxide.

7. The memory device of claim 1, further comprising:
a dielectric overlying the plurality of memory cells; and
a second plurality of memory cells having channels of a second amorphous metal oxide semiconductor formed overlying the dielectric.

8. The memory device of claim 7, wherein the amorphous metal oxide semiconductor and the second amorphous metal oxide semiconductor are the same type of amorphous metal oxide semiconductor.

9. The memory device of claim 1, wherein the amorphous metal oxide semiconductor has a sufficient charge carrier density to have a transmittance of less than 70%.

10. The memory device of claim 1, wherein the plurality of memory cells have channels on opposing sides of a pillar of the amorphous metal oxide semiconductor.

11. A method of forming a memory array, comprising:
forming an amorphous metal oxide semiconductor overlying a rigid support material;
forming memory cells using the amorphous metal oxide semiconductor; and
forming source/drain regions of the memory cells in the amorphous metal oxide semiconductor.

12. The method of claim 11, wherein forming an amorphous metal oxide semiconductor comprises forming an amorphous metal oxide semiconductor using a process selected from the group consisting of evaporative deposition, electron beam evaporation, pulsed-laser deposition and sputtering.

13. The method of claim 11, wherein forming the amorphous metal oxide semiconductor comprises forming an ionic amorphous metal oxide semiconductor.

14. The method of claim 13, wherein forming the ionic amorphous metal oxide semiconductor comprises forming an ionic amorphous metal oxide semiconductor selected from the group consisting of indium-doped tin oxide, zinc tin oxide, indium gallium zinc oxide, zinc oxide, tin oxide, indium gallium oxide, indium oxide and cadmium oxide.

15. The method of claim 11, wherein forming the amorphous metal oxide semiconductor comprises forming the amorphous metal oxide semiconductor at a temperature of less than 200° C.

16. A memory device, comprising:
a rigid support material;
a first layer of memory cells formed using a first amorphous metal oxide semiconductor overlying the rigid support material;
a first dielectric overlying the first layer of memory cells;
a second layer of memory cells formed using a second amorphous metal oxide semiconductor overlying the first dielectric;
a second dielectric overlying the second layer of memory cells;
a data line contact selectively connected to the first layer of memory cells and the second layer of memory cells; and
a source line contact selectively connected to the first layer of memory cells and the second layer of memory cells.

17. The memory device of claim 16, further comprising:
at least one additional layer of memory cells, each at least one additional layer of memory cells formed using an additional amorphous metal oxide semiconductor;
wherein the data line contact is further selectively connected to each at least one additional layer of memory cells; and
wherein the source line contact is further selectively connected to each at least one additional layer of memory cells.

18. The memory device of claim 16, wherein the data line contact is in contact with a first source/drain region of the first amorphous metal oxide semiconductor and passes through a first source/drain region of the second amorphous metal oxide semiconductor, and wherein the source line contact is in contact with a second source/drain region of the first amorphous metal oxide semiconductor and passes through a second source/drain region of the second amorphous metal oxide semiconductor.

19. The memory device of claim 18, wherein the source line contact is further in contact with more than one first source/drain regions of the first amorphous metal oxide semiconductor and passes through more than one first source/drain region of the second amorphous metal oxide semiconductor.

20. The memory device of claim 16, wherein the first amorphous metal oxide semiconductor and the second amorphous metal oxide semiconductor are each ionic amorphous metal oxide semiconductors and are each the same ionic amorphous metal oxide semiconductor.

21. A memory device, comprising:
a rigid support material;
a first NAND string of memory cells formed on a first amorphous metal oxide semiconductor overlying the rigid support material, wherein the first NAND string of memory cells comprises two or more memory cells coupled in series source-to-drain;
a first select line gate formed on the first amorphous metal oxide semiconductor and having a first source/drain region connected to a source/drain region of a memory cell on a first end of the first NAND string of memory cells;
a second select line gate formed on the first amorphous metal oxide semiconductor and having a first source/drain region connected to a source/drain region of a memory cell on a second end of the first NAND string of memory cells;
a first dielectric overlying the first NAND string of memory cells, the first select line gate and the second select line gate;
a second NAND string of memory cells formed on a second amorphous metal oxide semiconductor overlying the rigid support material, wherein the second NAND string of memory cells comprises two or more memory cells coupled in series source-to-drain;
a third select line gate formed on the second amorphous metal oxide semiconductor and having a first source/drain region connected to a source/drain region of a memory cell on a first end of the second NAND string of memory cells;
a fourth select line gate formed on the second amorphous metal oxide semiconductor and having a first source/drain region connected to a source/drain region of a memory cell on a second end of the second NAND string of memory cells;
a second dielectric overlying the second NAND string of memory cells, the third select line gate and the fourth select line gate;
a data line contact connected to a second source/drain region of the first select line gate and a second source/drain region of the second select line gate; and
a source line contact connected to a second source/drain region of the third select line gate and a second source/drain region of the fourth select line gate.

22. The memory device of claim 21, wherein the first NAND string of memory cells and the second NAND string of memory cells each comprise memory cells selected from the group consisting of floating-gate memory cells, nitride read-only memory cells, ferroelectric memory cells and phase-change memory cells.

23. The memory device of claim 21, wherein the first amorphous metal oxide semiconductor and the second amorphous metal oxide semiconductor are each selected from the group consisting of indium-doped tin oxide, zinc tin oxide, indium gallium zinc oxide, zinc oxide, tin oxide, indium gallium oxide, indium oxide and cadmium oxide.

24. A method of forming a memory array, comprising:
forming a first amorphous metal oxide semiconductor overlying a rigid support material;
forming a first NAND string of memory cells using the first amorphous metal oxide semiconductor;
forming a first select line gate having a first source/drain region connected to a source/drain region of a memory cell on a first end of the first NAND string of memory cells;
forming a second select line gate having a first source/drain region connected to a source/drain region of a memory cell on a second end of the first NAND string of memory cells;
forming a first dielectric over the first NAND string of memory cells, the first select line gate and the second select line gate;
forming a second amorphous metal oxide semiconductor overlying the first dielectric;
forming a second NAND string of memory cells using the second amorphous metal oxide semiconductor;
forming a third select line gate having a first source/drain region connected to a source/drain region of a memory cell on a first end of the second NAND string of memory cells;
forming a fourth select line gate having a first source/drain region connected to a source/drain region of a memory cell on a second end of the second NAND string of memory cells;
forming a second dielectric over the second NAND string of memory cells, the third select line gate and the fourth select line gate;
forming a data line contact extending through the second dielectric to at least a surface of the first amorphous metal oxide semiconductor and connected to a second source/drain region of the first select line gate and to a second source/drain region of the third select line gate; and
forming a source line contact extending through the second dielectric to at least a surface of the first amorphous metal oxide semiconductor and connected to a second source/drain region of the third select line gate and to a second source/drain region of the fourth select line gate.

25. The method of claim 24, further comprising:
forming at least one additional NAND string of memory cells, each using an additional amorphous metal oxide semiconductor.
